(19) United States
(12) Patent Application Publication
(10) Pub. No.: US 2025/0105179 A1
(43) Pub. Date: Mar. 27, 2025

(54) SEMICONDUCTOR CHIP AND SEMICONDUCTOR DEVICE

(71) Applicant: Mitsubishi Electric Corporation, Tokyo (JP)

(72) Inventors: Chikara INADA, Chiyoda-ku (JP); Erubi SUZUKI, Fukuoka-shi (JP); Yukimasa HIGASHI, Chiyoda-ku, Tokyo (JP)

(73) Assignee: Mitsubishi Electric Corporation, Tokyo (JP)

(21) Appl. No.: 18/829,387

(22) Filed: Sep. 10, 2024

(30) Foreign Application Priority Data
Sep. 26, 2023 (JP) 2023-162904

(51) Int. Cl. H01L 23/00; H01L 23/544; H01L 29/16

(52) U.S. Cl. CPC H01L 24/05; H01L 24/04; H01L 24/06; H10D 62/8325; H01L 23/544; H01L 2223/54426; H01L 2224/04034; H01L 2224/04042; H01L 2224/05552; H01L 2224/06051; H01L 2224/06131; H01L 2924/1515

(57) ABSTRACT

A semiconductor chip includes a semiconductor substrate including a first surface and having a semiconductor element formed on the semiconductor substrate, and a plurality of pads electrically connected to the semiconductor element and arranged on the first surface with a space interposed between each other. The plurality of pads include a first control pad and a second control pad. In a plan view, the second control pad includes a dissimilar shape portion dissimilar in outer shape in comparison with the first control pad.

### CROSS REFERENCE TO RELATED APPLICATIONS

This nonprovisional application is based on Japanese Patent Application No. 2023-162904 filed on Sep. 26, 2023 with the Japan Patent Office, the entire contents of which are hereby incorporated by reference.

### BACKGROUND OF THE INVENTION

### Field of the Invention

The present disclosure relates to a semiconductor chip and a semiconductor device.

### Description of the Background Art

A semiconductor device is known that includes a diced semiconductor chip and a mount substrate where the semiconductor chip is mounted. On the semiconductor chip, an alignment mark for positioning the semiconductor chip in the semiconductor device is provided.

Generally, alignment marks are formed on a semiconductor chip as two or more patterns in a region different from a wiring region such as a pad electrically connected to an external component (see WO 02/082540 for example).

### SUMMARY OF THE INVENTION

To suitably position a semiconductor chip in a semiconductor device, it is required to form a relatively large alignment mark that exhibits high recognizability on the semiconductor chip.

Thus, it has been difficult to achieve downsizing of a semiconductor chip in the case of forming an alignment mark that exhibits high recognizability in a region different from a wiring region such as a pad as mentioned above.

In particular, downsizing of a power semiconductor chip made from a silicon carbide (SiC) or the like has been promoted in recent years and it has been difficult to form an alignment mark that exhibits high recognizability in such a power semiconductor chip.

A main object of the present disclosure is to provide a semiconductor chip and a semiconductor device that enable downsizing while including an alignment mark that exhibits high recognizability.

A semiconductor chip according to the present disclosure includes a semiconductor substrate including a first surface and having a semiconductor element formed on the semiconductor substrate, and a plurality of pads electrically connected to the semiconductor element and arranged on the first surface with a space interposed between each other. The plurality of pads include a first pad and a second pad. In a plan view, the second pad includes a dissimilar shape portion dissimilar in outer shape in comparison with the first pad.

The above-described and other objects, features, aspects, and advantages of the present invention will be apparent from the following detailed description on the present invention, which will be understood in conjunction with the attached drawings.

### BRIEF DESCRIPTION OF THE DRAWINGS

FIG. 1 is a plan view for explaining a semiconductor chip according to Embodiment 1.

FIG. 2 is a partially enlarged plan view for explaining the semiconductor chip according to Embodiment 1.

FIG. 3 is a plan view for explaining a semiconductor device according to Embodiment 1.

FIG. 4 is a plan view for explaining a first variation of the semiconductor chip according to Embodiment 1.

FIG. 5 is a partially enlarged plan view for explaining a second variation of the semiconductor chip according to Embodiment 1.

FIG. 6 is a partially enlarged plan view for explaining a third variation of the semiconductor chip according to Embodiment 1.

FIG. 7 is a partially enlarged plan view for explaining a fourth variation of the semiconductor chip according to Embodiment 1.

FIG. 8 is a plan view for explaining a semiconductor chip according to Embodiment 2.

FIG. 9 is a plan view for explaining a semiconductor chip according to Embodiment 3.

FIG. 10 is a plan view for explaining a semiconductor chip according to Embodiment 4.

FIG. 11 is a partially enlarged cross sectional view taken along arrows XI-XI in FIG. 10.

### DESCRIPTION OF THE PREFERRED EMBODIMENTS

Embodiments of the present disclosure are described below with reference to the drawings. Hereinafter, the same or corresponding portions are denoted by the same reference characters and overlapping descriptions are not repeated.

### Embodiment 1

### <Configuration of Semiconductor Chip>

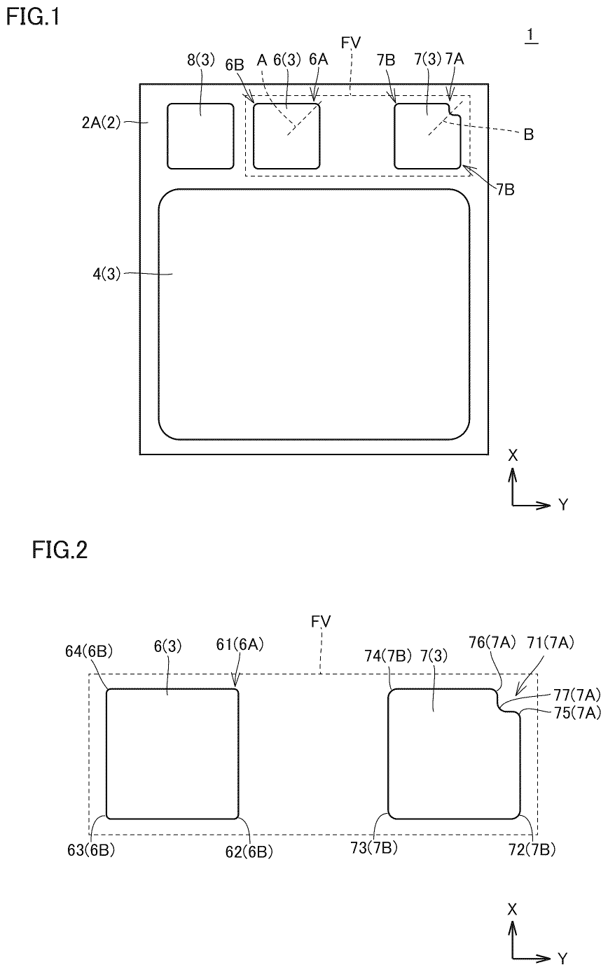

As illustrated in FIGS. 1 and 2, a semiconductor chip 1 according to Embodiment 1 includes a semiconductor substrate 2 and a plurality of pads 3.

Semiconductor substrate 2 includes a first surface 2A and a second surface 2B situated opposite to first surface 2A. A plan view as mentioned herein is based on a point of view from a direction orthogonal to first surface 2A. Semiconductor substrate 2 has a given element configuration formed on the semiconductor substrate including first surface 2A and second surface 2B. In a plan view, the outer shape of semiconductor substrate 2 is a rectangular shape for example. Semiconductor substrate 2 contains a silicon carbide (SiC), for example, as a base material.

A semiconductor element is, for example, a vertical semiconductor element. The semiconductor element is, for example, a power semiconductor element. The semiconductor element is, for example, a switching element such as an insulated gate bipolar transistor (IGBT), a gate commutated turn-off thyristor (GCT), or a metal oxide semiconductor field-effect transistor (MOSFET). The semiconductor element is provided, for example, so as to control a main current flowing to a main pad 4 in accordance with a signal input to a first control pad 6 and a second control pad 7, which are described below.

In a plan view, the outer shape of semiconductor substrate 2 is not limited to the rectangular shape. Semiconductor substrate 2 is not limited to the vertical semiconductor element. Semiconductor substrate 2 may contain a compound semiconductor material other than silicon (Si) or SiC as the base material. Semiconductor substrate 2 is not limited to the switching element but may be a rectification element such as a diode.

The plurality of pads 3 are arranged on first surface 2A of semiconductor substrate 2 with a space interposed between each other. Each of the plurality of pads 3 is electrically connected to the semiconductor element. For example, the plurality of pads 3 include main pad 4, first control pad 6, and second control pad 7. The main current of the semiconductor element flows to main pad 4. A signal to control the main current is input to and output from first control pad 6 and second control pad 7.

In a plan view, first control pad 6 and second control pad 7 are adjacent to main pad 4 and are arranged with a space interposed between main pad 4 and first control pad 6 and with a space interposed between main pad 4 and second control pad 7, respectively, in a first direction X along first surface 2A. In a plan view, first control pad 6 and second control pad 7 are adjacent to each other and are arranged with a space interposed between each other in a second direction Y along first surface 2A, which is perpendicular to first direction X. In a plan view, first control pad 6 and second control pad 7 are each arranged in a rectangular region corresponding to a field of view FV, which is described below. The space between first control pad 6 and second control pad 7 is, for example, larger than or equal to the width of first control pad 6 in direction Y.

In a plan view, second control pad 7 includes a dissimilar shape portion 7A dissimilar in outer shape in comparison with first control pad 6. From a different viewpoint, in a plan view, first control pad 6 includes a dissimilar shape portion 6A dissimilar in outer shape in comparison with second control pad 7.

Dissimilar shape portion 7A is, for example, part of an outer edge portion of second control pad 7. From a different viewpoint, in a plan view, first control pad 6 and second control pad 7 further include congruence portions 6B and 7B, respectively, which are situated in respective positions corresponding to each other in first control pad 6 and second control pad 7 and have respective outer shapes congruent with each other. The entire outer edge portion of second control pad 7 may be formed as dissimilar shape portion 7A.

In a plan view, dissimilar shape portions 6A and 7A are formed in respective positions corresponding to each other in first control pad 6 and second control pad 7.

Herein, the description that two dissimilar shape portions are formed in respective positions corresponding to each other in two pads in a plan view means that, in a plan view, directions from the respective centers toward the respective dissimilar shape portions in the two pads are the same as each other. In a plan view, relative positions of the respective congruence portions and dissimilar shape portions in the two pads are the same as each other. In a plan view, imaginary straight lines that connect the respective centers and dissimilar shape portions of the two pads are, for example, parallel to each other.

In a plan view, the direction from the center toward dissimilar shape portion 6A in first control pad 6 is the same as the direction from the center toward dissimilar shape portion 7A in second control pad 7. In a plan view, the relative positions of congruence portion 6B and dissimilar shape portion 6A in first control pad 6 is the same as the relative positions of congruence portion 7B and dissimilar shape portion 7A in second control pad 7. In a plan view, an imaginary straight line A that connects the center and dissimilar shape portion 6A in first control pad 6 is, for example, parallel to an imaginary straight line B that connects the center and dissimilar shape portion 7A in second control pad 7.

Dissimilar shape portion 7A can indicate the position and orientation of semiconductor chip 1 in a plan view when recognized at least together with dissimilar shape portion 6A. For example, by being recognized together with dissimilar shape portion 6A and congruence portions 6B and 7B in semiconductor chip 1 illustrated in FIG. 1, dissimilar shape portion 7A can indicate that the direction in which imaginary straight lines A and B are adjacent to each other is direction Y and the direction that is perpendicular to direction Y and oriented toward the side on which dissimilar shape portion 7A is formed in relation to the center of second control pad 7 in a plan view is direction X.

In a plan view, the outer shape of first control pad 6 is, for example, a rectangular shape with round corners, where four corners are rounded. First control pad 6 includes a plurality of corner portions 61, 62, 63, and 64, and a plurality of side portions that each connect two of the corner portions adjacent to each other. In a plan view, for example, first control pad 6 has rotational symmetry about the center of first control pad 6.

In a plan view, second control pad 7 includes a plurality of corner portions 71, 72, 73, and 74, and a plurality of side portions that each connect two of the corner portions adjacent to each other. Corner portion 71 is made up of, for example, a plurality of corner portions 75, 76, and 77, and a plurality of side portions that connect these corner portions. In a plan view, the plurality of corner portions 71, 72, 73, and 74 are situated in positions corresponding to the plurality of corner portions 61, 62, 63, and 64, respectively. In a plan view, second control pad 7 has no rotational symmetry about the center of second control pad 7.

For example, second control pad 7 includes one dissimilar shape portion 7A. For example, dissimilar shape portion 7A is formed in corner portion 71 of second control pad 7. From a different viewpoint, for example, dissimilar shape portion 6A is formed in corner portion 61 of first control pad 6. In a plan view, for example, corner portion 71 is situated closest to a corner portion of semiconductor substrate 2 among the plurality of corner portions of second control pad 7.

For example, dissimilar shape portion 7A includes a depressed portion whose outer shape is a depressed shape in comparison with first control pad 6. Dissimilar shape portion 7A includes the plurality of corner portions 75, 76, and 77. The number of corner portions of second control pad 7 is larger than the number of corner portions of first control pad 6. The shape of the depressed portion is not particularly limited. The size of the depressed portion is not particularly limited as long as a mounting apparatus used in a step of mounting semiconductor chip 1 on a mount substrate in a method for manufacturing a semiconductor device 100, which is described below, can recognize it as an alignment mark.

Congruence portions 6B and 7B are formed by the respective remainders of the outer edge portions of first control pad 6 and second control pad 7 except dissimilar shape portions 6A and 7A. Congruence portion 7B includes other corner portions 72, 73, and 74 than corner portion 71, and the plurality of side portions, which are included in the outer edge portion of second control pad 7. Congruence portion 6B includes other corner portions 62, 63, and 64 than corner portion 61, and the plurality of side portions, which are included in the outer edge portion of first control pad 6.

In a plan view, the outer shape of main pad 4 is, for example, a rectangular shape with round corners, where four corners are rounded. In a plan view, for example, the outer shapes of first control pad 6 and main pad 4 are each a rectangular shape with round corners, where four corners are rounded.

In a plan view, the footprint of main pad 4 is larger than each of the respective footprints of first control pad 6 and second control pad 7. In a plan view, the footprint of main pad 4 is, for example, larger than the total of the respective footprints of first control pad 6 and second control pad 7.

The plurality of pads 3 may further include a third control pad 8. For example, third control pad 8 is arranged so as to be adjacent to main pad 4 with a space interposed between main pad 4 and third control pad 8 in first direction X and is arranged with a space interposed between first control pad 6 and third control pad 8 in second direction Y.

On first surface 2A, semiconductor chip 1 does not include an alignment mark having no electrical connection to the semiconductor element, that is, a pattern that functions solely as an alignment mark.

For example, semiconductor chip 1 further includes a protection film (not illustrated), which is formed so as to surround the plurality of pads 3 on first surface 2A.

### <Method for Manufacturing Semiconductor Chip>

Semiconductor chip 1 can be manufactured in a similar manner to how a conventional semiconductor chip is manufactured. Second control pad 7 with dissimilar shape portion 7A can be formed by a given method and, for example, can be formed by performing patterning on a conductive film made on first surface 2A using a mask suited to dissimilar shape portion 7A.

### <Configuration of Semiconductor Device>

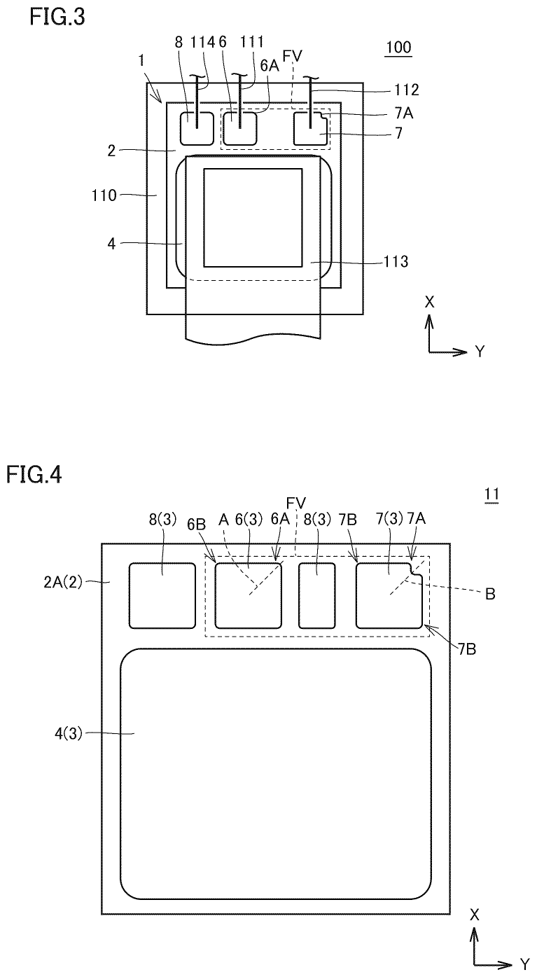

As illustrated in FIG. 3, semiconductor device 100 according to Embodiment 1 includes semiconductor chip 1, a mount substrate 110, a first connection member 111, a second connection member 112, a third connection member 113, a fourth connection member 114, and a sealing member (not illustrated).

Semiconductor chip 1 is mounted on mount substrate 110. A region where semiconductor chip 1 is to be mounted is designated on mount substrate 110 in advance and semiconductor chip 1 is bonded on the region using a bonding material. Mount substrate 110 may be a substrate formed of metal, such as copper or aluminum. Alternatively, mount substrate 110 may be a substrate whose base material is a ceramic, resin, or the like.

First connection member 111 is electrically connected to first control pad 6. Second connection member 112 is electrically connected to second control pad 7. Third connection member 113 is electrically connected to main pad 4. Fourth connection member 114 is electrically connected to third control pad 8. First connection member 111, second connection member 112, third connection member 113, and fourth connection member 114 are each electrically connected to, for example, another member (not illustrated) included in semiconductor device 100. First connection member 111, second connection member 112, and fourth connection member 114 are wires or ribbons for example. Third connection member 113 is a lead terminal for example.

In semiconductor device 100, semiconductor chip 1 is sealed with the sealing member.

### <Method for Manufacturing Semiconductor Device>

Semiconductor device 100 can be manufactured in a similar manner to how a conventional semiconductor device is manufactured. The method for manufacturing semiconductor device 100 includes a first step of preparing semiconductor chip 1 and a second step of mounting semiconductor chip 1 prepared in the first step on mount substrate 110.

In the second step, first control pad 6 and second control pad 7 are recognized by the mounting apparatus concurrently and utilized as alignment marks. The mounting apparatus can grasp the position and orientation of semiconductor chip 1 in a plan view by recognizing dissimilar shape portions 6A and 7A concurrently in its field of view FV (see FIG. 3).

The method for manufacturing semiconductor device 100 further includes a third step after the second step. In the third step, first connection member 111, second connection member 112, third connection member 113, and fourth connection member 114 are electrically connected to first control pad 6, second control pad 7, main pad 4, and third control pad 8, respectively.

### Effects

In semiconductor chip 1, second control pad 7 (a second pad) includes dissimilar shape portion 7A dissimilar in outer shape in comparison with first control pad 6 (a first pad). Thus, in semiconductor device 100, first control pad 6 and second control pad 7 serve as wiring components for electrically connecting the semiconductor element in semiconductor chip 1 to an external component and can also function as alignment marks. Thus, the footprints of first control pad 6 and second control pad 7 are smaller than the total of the footprint of a pad having a footprint equivalent to these and the footprint of an alignment mark formed in a different region from the pad. As a result, semiconductor chip 1 enables downsizing while including an alignment mark that exhibits high recognizability, which is greater than or equal to that in a conventional semiconductor chip including a pad electrically connected to an external component and an alignment mark formed in a different region from the pad.

Furthermore, first control pad 6 and second control pad 7 that can function as alignment marks are wiring components as described above, and accordingly, can be made larger than an alignment mark formed separately from a pad in a conventional semiconductor chip. Thus, semiconductor chip 1 enables downsizing while including an alignment mark that exhibits higher recognizability than that in the aforementioned conventional semiconductor chip. This semiconductor chip 1 is suitable for a power semiconductor chip for which decrease in chip size is promoted, such as a power semiconductor chip whose base material is a silicon carbide (SiC).

In semiconductor chip 1, first control pad 6 and second control pad 7 further include congruence portions 6B and 7B, respectively. In this case, the orientation of semiconductor chip 1 can be recognized on the basis of information on the position of dissimilar shape portion 7A relative to each of dissimilar shape portion 6A and congruence portion 7B. Further in this case, second control pad 7 including dissimilar shape portion 7A and congruence portion 7B can be formed easily as what includes at least one depressed portion in comparison with first control pad 6.

In semiconductor chip 1, first control pad 6 and second control pad 7 are adjacent to each other among the plurality of pads 3. Accordingly, the field of view FV needed to concurrently recognize first control pad 6 and second control pad 7 of semiconductor chip 1 can be made smaller than that in a case where first control pad 6 and second control pad 7 would not be adjacent to each other. Thus, first control pad 6 and second control pad 7 can be observed under higher magnification, and as a result, the recognizability of dissimilar shape portion 7A is increased and the above-described mounting of semiconductor chip 1 can be performed with higher efficiency. Generally, the aforementioned conventional semiconductor chip includes one alignment mark formed in one end portion of a chip in a plan view and another alignment mark formed in the other end portion of the chip in a plan view. Thus, generally in the step of mounting the conventional semiconductor chip on the mount substrate, the alignment of the semiconductor chip is performed by the mounting apparatus recognizing the two alignment marks individually and sequentially. In contrast, in semiconductor chip 1, the alignment can be performed by first control pad 6 and second control pad 7 being recognized concurrently. Accordingly, the above-described mounting can be performed with higher efficiency in comparison with the aforementioned conventional semiconductor chip.

Semiconductor device 100 includes semiconductor chip 1 and thus can be decreased in size in comparison with a semiconductor device including the conventional semiconductor chip. Moreover, by the method for manufacturing semiconductor device 100, semiconductor chip 1 is mounted on mount substrate 110 with first control pad 6 and second control pad 7 serving as alignment marks. Accordingly, the manufacture efficiency of semiconductor device 100 is higher than that of the conventional semiconductor device.

### <Variations>

As illustrated in FIG. 4, third control pad 8 may be arranged between first control pad 6 and second control pad 7. First control pad 6 and second control pad 7 are not necessarily required to be adjacent to each other. Second control pad 7 may be arranged so as to be adjacent to third control pad 8. Also in this case, first control pad 6 and second control pad 7 can be formed as alignment marks that are larger and exhibit higher recognizability than the alignment marks of the aforementioned conventional semiconductor chip.

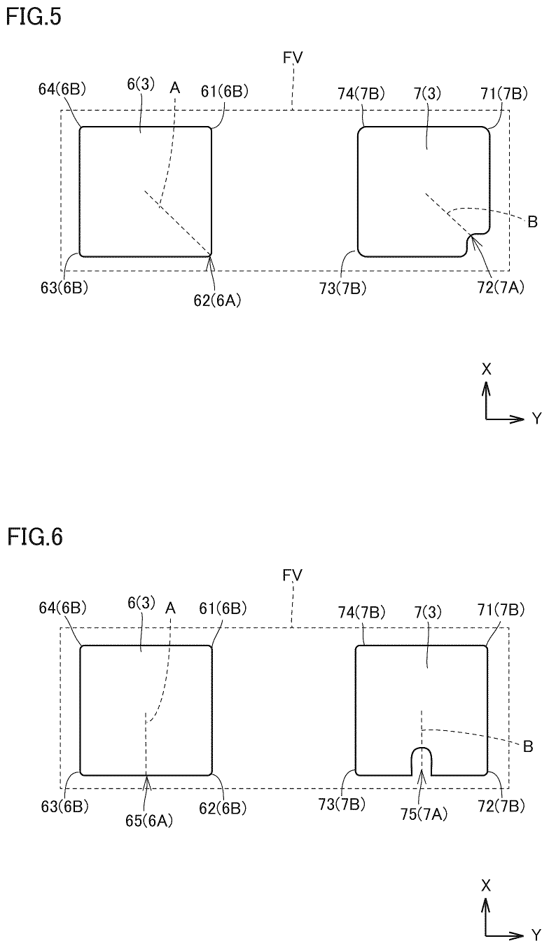

In semiconductor chip 1, dissimilar shape portion 7A is just required to be formed so as to have a given shape in a given position in the outer edge portion of second control pad 7. As illustrated in FIG. 5, dissimilar shape portion 7A may be formed in corner portion 72. In this case, corner portion 71 may be included in congruence portion 7B. As illustrated in FIG. 6, dissimilar shape portion 7A may be formed in one of the side portions. In this case, the plurality of corner portions may be included in congruence portion 7B.

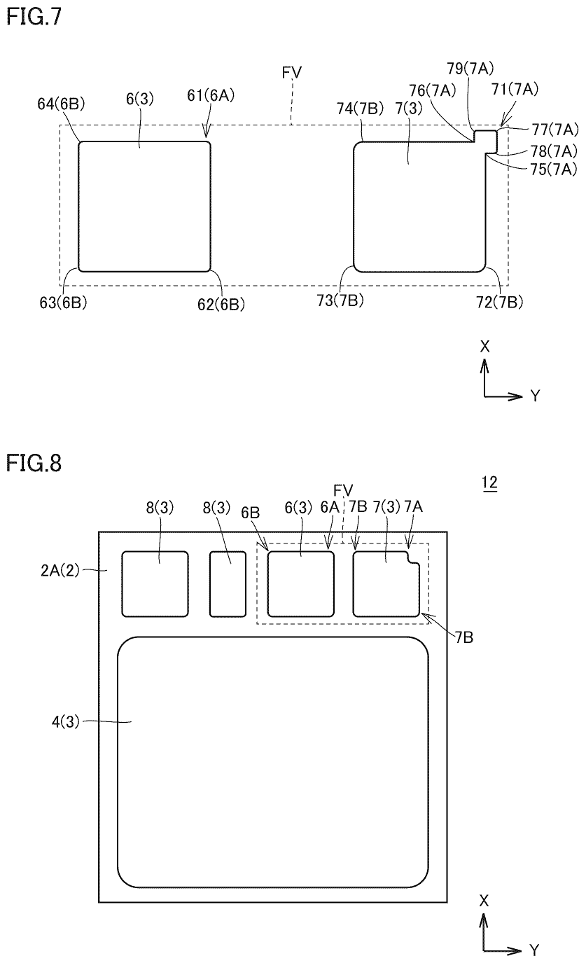

As illustrated in FIG. 7, for example, dissimilar shape portion 7A may include a projecting portion whose outer shape is a projecting shape in comparison with first control pad 6. In a plan view, second control pad 7 has an outer shape obtained, for example, when one of the corner portions of a relatively small rectangular shape with round corners is superposed on one of the corner portions of a relatively large rectangular shape with round corners. Corner portion 71 is made up of, for example, a plurality of corner portions 75, 76, 77, 78, and 79, and a plurality of side portions that connect these corner portions.

Dissimilar shape portion 7A may include both the above-described depressed portion and the above-described projecting portion. For example, at least one of corner portions 77, 78, and 79 illustrated in FIG. 7 may include the depressed portion.

Dissimilar shape portion 7A is preferably formed in at least any one of the plurality of corner portions 71, 72, 73, and 74 of second control pad 7. Accordingly, even when the area that dissimilar shape portion 7A can occupy is limited, the degree of flexibility in the shape and arrangement of dissimilar shape portion 7A can be increased in comparison with a case where dissimilar shape portion 7A is formed in one of the plurality of side portions.

### Embodiment 2

Unless otherwise described particularly, a semiconductor chip 12 and a semiconductor device according to Embodiment 2 have the same configuration, and functions and effects as those according to Embodiment 1 described above. Thus, the same constituent elements as those in Embodiment 1 described above are denoted by the same reference characters and are not explained repeatedly.

As illustrated in FIG. 8, in semiconductor chip 12 according to Embodiment 2, the space between a second control pad 7 and a first control pad 6 in a second direction Y is smaller than the width of second control pad 7 in second direction Y. The space between second control pad 7 and first control pad 6 in second direction Y is, for example, smaller than any other space between two pads of a plurality of pads 3, which are adjacent to each other in a first direction X or second direction Y.

In semiconductor chip 12, the space between second control pad 7 and first control pad 6 in second direction Y can be shorter than that in semiconductor chip 1. Thus, a field of view FV needed to concurrently recognize first control pad 6 and second control pad 7 of semiconductor chip 12 can be smaller than the field of view FV needed to concurrently recognize first control pad 6 and second control pad 7 of semiconductor chip 1. Accordingly, in semiconductor chip 12, the recognizability of a dissimilar shape portion 7A is further increased and the above-described mounting of semiconductor chip 12 can be performed with higher efficiency in comparison with semiconductor chip 1.

Semiconductor chip 12 according to Embodiment 2 can be varied similarly to semiconductor chip 1 according to Embodiment 1.

### Embodiment 3

Unless otherwise described particularly, a semiconductor chip 13 and a semiconductor device according to Embodiment 3 have the same configuration, and functions and effects as those according to Embodiment 1 described above. Thus, the same constituent elements as those in Embodiment 1 described above are denoted by the same reference characters and are not explained repeatedly.

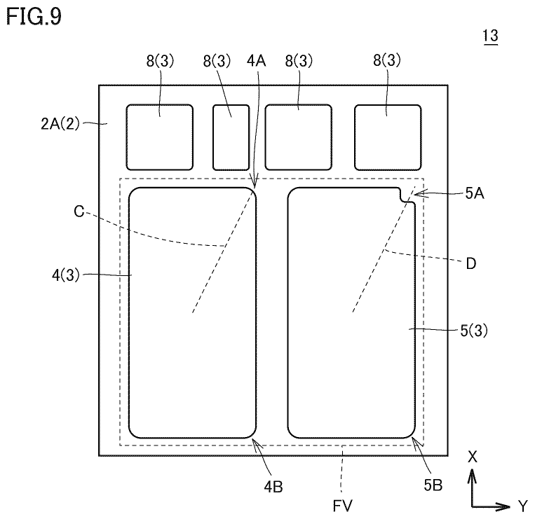

As illustrated in FIG. 9, in semiconductor chip 13 according to Embodiment 3, a plurality of pads 3 include a first main pad 4 (a first pad), a second main pad 5 (a second pad), and a plurality of control pads 8. Second main pad 5 is arranged with a space interposed between first main pad 4 and second main pad 5 in a second direction Y. First main pad 4 and second main pad 5 are arranged with a space interposed between the plurality of control pads 8 and first main pad 4 and with a space interposed between the plurality of control pads 8 and second main pad 5, respectively, in a first direction X. The footprint of each of first main pad 4 and second main pad 5 is larger than the footprint of each of the plurality of control pads 8.

In a plan view, second main pad 5 includes a dissimilar shape portion 5A dissimilar in outer shape in comparison with first main pad 4. From a different viewpoint, in a plan view, first main pad 4 includes a dissimilar shape portion 4A dissimilar in outer shape in comparison with second main pad 5.

For example, dissimilar shape portion 5A is formed in a corner portion of second main pad 5. In a plan view, for example, dissimilar shape portion 5A is formed in one corner portion included in a plurality of corner portions of second main pad 5 and situated on the side of the plurality of control pads 8.

Dissimilar shape portion 5A includes a depressed portion whose outer shape is a depressed shape, for example, in comparison with first main pad 4.

For example, dissimilar shape portion 5A is part of an outer edge portion of second main pad 5. From a different viewpoint, in a plan view, first main pad 4 and second main pad 5 further include congruence portions 4B and 5B, respectively, which are situated in respective positions corresponding to each other in first main pad 4 and second main pad 5 and have respective outer shapes congruent with each other.

Dissimilar shape portions 4A and 5A are just required to have similar configurations to those of dissimilar shape portions 6A and 7A of semiconductor chip 1, respectively. Congruence portions 4B and 5B are just required to have similar configurations to those of congruence portions 6B and 7B of semiconductor chip 1, respectively. The entire outer edge portion of second main pad 5 may be formed as dissimilar shape portion 5A.

In semiconductor chip 13, first main pad 4 and second main pad 5 are recognized concurrently by a mounting apparatus and utilized as alignment marks. First main pad 4 and second main pad 5 are larger than first control pad 6 and second control pad 7, and thus, can be formed as alignment marks that exhibit higher recognizability than first control pad 6 and second control pad 7.

Semiconductor chip 13 according to Embodiment 3 can also be varied similarly to semiconductor chip 1 according to Embodiment 1.

### Embodiment 4

Unless otherwise described particularly, a semiconductor chip 14 and a semiconductor device according to Embodiment 4 have the same configuration, and functions and effects as those according to Embodiment 1 described above. Thus, the same constituent elements as those in Embodiment 1 described above are denoted by the same reference characters and are not explained repeatedly.

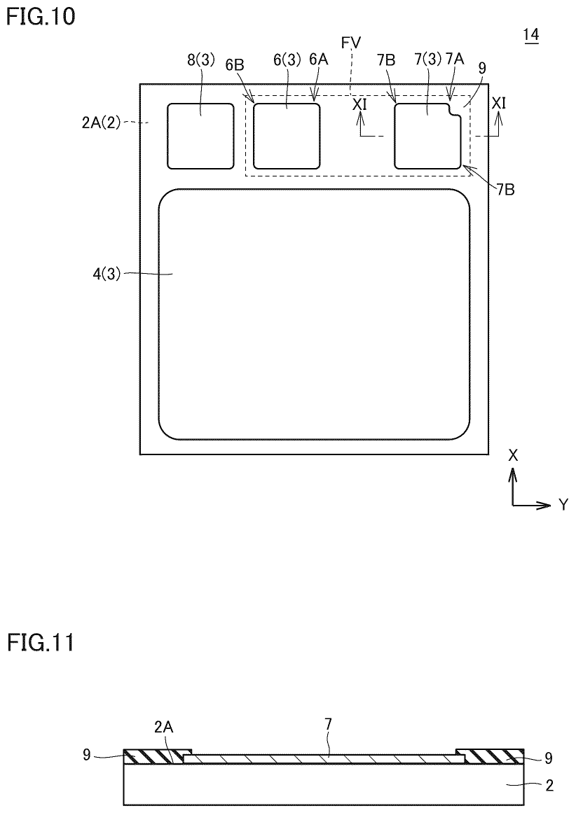

As illustrated in FIGS. 10 and 11, semiconductor chip 14 according to Embodiment 4 further includes an outer edge portion 9 arranged so as to surround a second control pad 7 (a second pad) on a first surface 2A of a semiconductor substrate 2. In a plan view, outer edge portion 9 can be visually recognized concurrently with second control pad 7 and its dissimilar shape portion 7A. Outer edge portion 9 is arranged at least in a field of view FV.

The visible light reflectivity of a material from which outer edge portion 9 is formed is lower than the visible light reflectivity of a material from which second control pad 7 is formed. The material from which second control pad 7 is formed is a conductive material and contains at least any selected from a group consisting of, for example, gold (Au), copper (Cu), nickel (Ni), and aluminum (Al). The material from which outer edge portion 9 is formed may be a given material only when the material is lower in visible light reflectivity than the material from which second control pad 7 is formed, but is preferably a material having electrical insulation properties. The material from which outer edge portion 9 is formed is, for example, polyimide or a nitride film. In this case, for example, outer edge portion 9 may be formed to surround each of a plurality of pads 3 as part of a protection film.

Semiconductor chip 14 may further include a protection film arranged so as to surround each of the plurality of pads 3 and outer edge portion 9.

In semiconductor chip 14, a dissimilar shape portion 7A of second control pad 7 and outer edge portion 9 are largely different in hue, and thus, a first control pad 6, second control pad 7, and outer edge portion 9 can function as alignment marks that exhibit high recognizability.

Although embodiments of the present disclosure have been described, it should be understood that the herein-disclosed embodiments are presented by way of illustration and example in every respect and are not to be taken by way of limitation. The scope of the present disclosure is defined by the claims and intended to include all changes within the purport and scope equivalent to the claims.

What is claimed is:

1. A semiconductor chip comprising:
a semiconductor substrate including a first surface and having a semiconductor element formed on the semiconductor substrate; and
a plurality of pads electrically connected to the semiconductor element and arranged on the first surface with a space interposed between each other, wherein
the plurality of pads include a first pad and a second pad, and
in a plan view, the second pad includes a dissimilar shape portion dissimilar in outer shape in comparison with the first pad.

2. The semiconductor chip according to claim 1, wherein in the plan view, the first pad and the second pad further include respective congruence portions situated in respective positions corresponding to each other in the first pad and the second pad and having respective outer shapes congruent with each other.

3. The semiconductor chip according to claim 1, wherein
in the plan view, the first pad and the second pad further include respective corner portions situated in respective positions corresponding to each other in the first pad and the second pad, and
the dissimilar shape portion is provided in the corner portion of the second pad.

4. The semiconductor chip according to claim 1, wherein the dissimilar shape portion of the second pad includes a depressed portion whose outer shape is a depressed shape or a projecting portion whose outer shape is a projecting shape in comparison with the first pad.

5. The semiconductor chip according to claim 1, wherein the first pad and the second pad are adjacent to each other among the plurality of pads.

6. The semiconductor chip according to claim 1, wherein
the plurality of pads further include a third pad to which a main current of the semiconductor element flows, and
a signal to control the main current is input to and output from the first pad and the second pad.

7. The semiconductor chip according to claim 1, wherein
a main current of the semiconductor element flows to the first pad and the second pad, and
the plurality of pads further include a third pad and a fourth pad, and a signal to control the main current is input to and output from the third pad and the fourth pad.

8. The semiconductor chip according to claim 1, further comprising
an outer edge portion arranged to surround the second pad on the first surface and visually recognizable in the plan view, wherein
visible light reflectivity of a material from which the outer edge portion is formed is lower than visible light reflectivity of a material from which the second pad is formed.

9. The semiconductor chip according to claim 1, wherein the semiconductor element contains a silicon carbide.

10. A semiconductor device comprising:
the semiconductor chip according to claim 1;
a mount substrate on which the semiconductor chip is mounted;
a first connection member electrically connected to the first pad; and
a second connection member electrically connected to the second pad.

11. A semiconductor device comprising:
the semiconductor chip according to claim 2;
a mount substrate on which the semiconductor chip is mounted;
a first connection member electrically connected to the first pad; and
a second connection member electrically connected to the second pad.

12. A semiconductor device comprising:
the semiconductor chip according to claim 3;
a mount substrate on which the semiconductor chip is mounted;
a first connection member electrically connected to the first pad; and
a second connection member electrically connected to the second pad.

13. A semiconductor device comprising:
the semiconductor chip according to claim 4;
a mount substrate on which the semiconductor chip is mounted;
a first connection member electrically connected to the first pad; and
a second connection member electrically connected to the second pad.

14. A semiconductor device comprising:
the semiconductor chip according to claim 5;
a mount substrate on which the semiconductor chip is mounted;
a first connection member electrically connected to the first pad; and
a second connection member electrically connected to the second pad.

15. A semiconductor device comprising:
the semiconductor chip according to claim 6;
a mount substrate on which the semiconductor chip is mounted;
a first connection member electrically connected to the first pad; and
a second connection member electrically connected to the second pad.

16. A semiconductor device comprising:
the semiconductor chip according to claim 7;
a mount substrate on which the semiconductor chip is mounted;
a first connection member electrically connected to the first pad; and
a second connection member electrically connected to the second pad.

17. A semiconductor device comprising:
the semiconductor chip according to claim 8;
a mount substrate on which the semiconductor chip is mounted;
a first connection member electrically connected to the first pad; and
a second connection member electrically connected to the second pad.

18. A semiconductor device comprising:
the semiconductor chip according to claim 9;
a mount substrate on which the semiconductor chip is mounted;
a first connection member electrically connected to the first pad; and
a second connection member electrically connected to the second pad.
